(19) United States
(12) Patent Application Publication
(10) Pub. No.: US 2026/0293633 A1
(43) Pub. Date: Sep. 24, 2026

(54) INTEGRATED JUNCTION SILICIDE AND SELECTIVE METAL CAPPING WITH PULLBACK

(71) Applicant: Applied Materials, Inc., Santa Clara, CA (US)

(72) Inventors: Wei ZHANG, Sunnyvale, CA (US); Shumao ZHANG, San Jose, CA (US); Le ZHANG, Santa Clara, CA (US); Chih-Hsun HSU, Santa Clara, CA (US); Jiang LU, Milpitas, CA (US)

(21) Appl. No.: 19/082,594

(22) Filed: Mar. 18, 2025

(51) Int. Cl. H01L 21/768; C23C 14/06; C23C 14/54

(52) U.S. Cl. CPC H10W 20/066; C23C 14/0605; C23C 14/541; C23C 14/548; H10W 20/037; H10W 20/055; H10W 20/056

(57) ABSTRACT

Methods for forming low resistivity contacts for semiconductor device formation are provided. A carbon-containing passivation layer is exposed to a first hydrogen plasma to etch a first portion of the carbon-containing passivation layer exposing at least a first portion of a metal silicide layer formed over sidewall surfaces that define an opening while a second portion of the carbon-containing passivation layer remains over a second portion of the metal silicide layer formed over a bottom surface that defines the opening. The first portion of the metal silicide layer is exposed to an etchant gas to remove the first portion of the metal silicide layer formed over the sidewall surfaces. The second portion of the carbon-containing passivation layer remaining over the bottom surface is exposed to a second hydrogen plasma to remove the second portion of the carbon-containing passivation layer exposing the second portion of the metal silicide layer.

### BACKGROUND

### Field

Embodiments disclosed herein generally relate to methods for forming low resistivity contacts for semiconductor device formation.

### Description of the Related Art

Integrated circuits have evolved into complex devices that can include billions of transistors, capacitors, and resistors on a single chip. In the course of integrated circuit evolution, functional density, that is, the number of interconnected devices per chip area, has generally increased while geometry size, that is, the smallest component (or line) that can be created using a fabrication process, has decreased.

Microelectronic devices are fabricated on a semiconductor substrate as integrated circuits in which various conductive layers are interconnected with one another to permit electronic signals to propagate within the device. Examples of such devices include memory, for example, dynamic random access memory (DRAM) and logic devices, including both planar and three-dimensional structures. Three-dimensional structures include fin field-effect transistor (finFET) or metal-oxide-semiconductor field-effect transistor (MOSFET) devices.

An example of a finFET or MOSFET device includes a gate electrode on a gate dielectric layer on a surface of a semiconductor substrate. Source/drain regions are provided along opposite sides of the gate electrode. The source and drain regions are generally heavily doped regions of the semiconductor substrate. Usually a silicide layer, for example a titanium silicide layer, is used to form a reliable contact at the formed source and drain regions.

Reliable contacts with a low resistivity are desirable in semiconductor manufacturing. However, when contacts have high resistance, the contacts produce poor connections reducing the performance of the packaged semiconductor structures.

Thus, there is a need for methods and systems for forming reliable contacts with low resistivity is semiconductor devices.

### SUMMARY

Embodiments disclosed herein generally relate to methods for forming low resistivity contacts for semiconductor device formation.

In one aspect, a method of forming a contact structure on a semiconductor substrate is provided. The method includes depositing a carbon-containing passivation layer over a metal silicide layer, the metal silicide layer formed over a bottom surface and sidewall surfaces that define an opening of a feature. The method further includes trimming the carbon-containing passivation layer by exposing the carbon-containing passivation layer to a first hydrogen plasma so that a first portion of the carbon-containing passivation layer is etched away exposing at least a first portion of the metal silicide layer formed over the sidewall surfaces while a second portion of the carbon-containing passivation layer remains over a second portion of the metal silicide layer formed over the bottom surface. The method further includes exposing the first portion of the metal silicide layer to an etchant gas to remove the first portion of the metal silicide layer formed over the sidewall surfaces. The method further includes exposing the second portion of the carbon-containing passivation layer remaining over the bottom surface to a second hydrogen plasma so that the second portion of the carbon-containing passivation layer is removed exposing the second portion of the metal silicide layer formed over the bottom surface.

Embodiments may include one or more of the following. The metal silicide layer includes titanium silicide. The method further includes depositing a metal gapfill material over the second portion of the metal silicide layer formed over the bottom surface. The metal gapfill material includes titanium, tungsten, molybdenum, or combinations thereof. Depositing the metal gapfill material includes a bottom-up growth process. The carbon-containing passivation layer includes forming an inductively coupled plasma including argon and methane. Exposing the carbon-containing passivation layer to the first hydrogen plasma includes flowing hydrogen gas at a first flow rate and at a first power. Exposing the second portion of the carbon-containing passivation layer remaining over the bottom surface to the second hydrogen plasma includes flowing hydrogen gas at a second flow rate and at a second power, the second flow rate greater than the first flow rate and the second power less than the first power. The etchant gas includes chlorine and methane.

In another aspect, a method of forming a contact structure on a semiconductor substrate is provided. The method includes forming a metal silicide layer over a surface of the contact structure. The contact structure includes a feature formed in a surface of the semiconductor substrate. The feature includes a bottom surface and sidewall surfaces that define an opening, which include a dielectric material. The metal silicide layer is formed over the sidewall surfaces and the bottom surface. The method further includes performing a selective etch process. The selective etch process includes a deposition operation. The deposition operation includes forming a carbon-containing passivation layer over the metal silicide layer. The selective etch process further includes a trim operation. The trim operation includes exposing the carbon-containing passivation layer to a first hydrogen plasma so that a first portion of the carbon-containing passivation layer is etched away exposing at least a first portion of the metal silicide layer formed over the sidewall surfaces while a second portion of the carbon-containing passivation layer remains over a second portion of the metal silicide layer formed over the bottom surface. The selective etch process further includes an etch operation. The etch operation includes exposing the first portion of the metal silicide layer formed over the sidewall surfaces to an etchant gas to remove the first portion of the metal silicide layer formed over the sidewall surfaces. The selective etch process further includes a carbon removal operation. The carbon removal operation includes exposing the second portion of the carbon-containing passivation layer to a second hydrogen plasma so that the second portion of the carbon-containing passivation layer is removed exposing the second portion of the metal silicide layer formed over the bottom surface. The method further includes depositing a metal gapfill material over the second portion of the metal silicide layer formed over the bottom surface.

Embodiments may include one or more of the following. The metal silicide layer includes titanium silicide. The metal gapfill material includes titanium, tungsten, molybdenum, or combinations thereof. Forming the carbon-containing passivation layer over the metal silicide layer includes delivering a carbon-containing precursor that includes methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), isomers thereof, or a combination thereof to the feature; delivering the carbon-containing precursor to the feature at a pressure of about 5 mT to about 100 mT; and heating the semiconductor substrate to a temperature of about 300 °C to 550 °C. Exposing the carbon-containing passivation layer to the first hydrogen plasma includes delivering a hydrogen containing precursor that includes H₂, H₂°, H₂O₂, or a combination thereof to the feature; delivering the hydrogen containing precursor to the feature at a pressure of about 50 mT to about 20 T; and heating the semiconductor substrate to a temperature of about 120 °C to 350 °C. Exposing the first portion of the metal silicide layer to the etchant gas includes delivering an inductively coupled plasma including Cl₂ to the feature at a flow rate of about 60 sccm to about 500 sccm, a pressure of about 5 mT to about 100 mT, and a temperature of about 0 °C to about 50 °C. Exposing the second portion of the carbon-containing passivation layer to the second hydrogen plasma includes delivering a hydrogen containing precursor that includes H₂, H₂°, H₂O₂, or a combination thereof to the feature; delivering the hydrogen containing precursor to the feature at a pressure of about 50 mT to about 20 T; and heating the semiconductor substrate to a temperature of about 120 °C to 350 °C. Depositing the metal gapfill material includes depositing the metal gapfill material using a chemical vapor deposition process.

In yet another aspect, a processing system is provided. The system includes a first processing chamber and a system controller. The system controller includes a memory for storing computer readable instructions and a processor coupled to the memory, the processor configured by the computer readable instructions that when executed by the processor perform a plurality of operations. The plurality of operations include depositing a carbon-containing passivation layer over a metal silicide layer, the metal silicide layer formed over a bottom surface and sidewall surfaces that define an opening of a feature formed on a semiconductor substrate. The plurality of operations further include trimming the carbon-containing passivation layer by exposing the carbon-containing passivation layer to a first hydrogen plasma so that a first portion of the carbon-containing passivation layer is etched away exposing at least a first portion of the metal silicide layer formed over the sidewall surfaces while a second portion of the carbon-containing passivation layer remains over the bottom surface. The plurality of operations further include exposing the first portion of the metal silicide layer to an etchant gas to remove the first portion of the metal silicide layer formed over the sidewall surfaces. The plurality of operations further include exposing the second portion of the carbon-containing passivation layer remaining over the bottom surface to a second hydrogen plasma so that the second portion of the carbon-containing passivation layer is removed exposing the second portion of the metal silicide layer formed over the bottom surface.

Embodiments may include one or more of the following. Depositing the carbon-containing passivation layer, trimming the carbon-containing passivation layer, exposing the first portion of the metal silicide layer to the etchant gas, and exposing the second portion of the carbon-containing passivation layer remaining over the bottom surface to the second hydrogen plasma are performed in the first processing chamber. The metal silicide layer includes titanium silicide.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic top view of a multi-chamber processing system in accordance with one or more embodiments of the present disclosure.

FIG. 2 illustrates a process flow diagram of a method of forming a metal silicide layer in a semiconductor structure in accordance with one or more embodiments of the present disclosure.

FIGS. 3A-3G illustrate cross-sectional views of a portion of a semiconductor structure corresponding to various states of the method of FIG. 2 in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to methods for forming low resistivity contacts for semiconductor device formation. In a traditional contact junction formation process, a feature also referred to as a cavity, a via, or a trench, is fabricated in the semiconductor substrate. In one example, middle-of-the-line (MOL) contact junctions allow connections between front-end-of-the-line (FEOL) semiconductor structures and back-end-of-the-line (BEOL) interconnects. Contacts with a low resistivity are desirable in semiconductor devices. However, when MOL contacts have high resistance, the contacts produce poor connections between the FEOL structures and the BEOL packaging interconnects, reducing the performance of the packaged semiconductor structures.

In traditional contact formation processes, a conformal titanium silicide (TiSi) layer is formed on a silicon or silicon germanium connection as a capping layer and then nitrided to form titanium silicon nitride (TiSiN) to prevent oxidation of the TiSi. The final silicide capping layer is a bilayer of TiSi and TiSiN that is formed over the field, sidewalls and contact regions formed on the substrate. The inventors have observed, however, that the TiSiN layer has a high resistivity (approximately 300 μohms-cm for a thickness of approximately 6 nm). The TiSi(N)/W on the field and sidewall then need to be removed by a wet pull-back process, where physical vapor deposition (PVD) tungsten (W) only remains at the bottom of the via. Due to PVD technology limitations, it is challenging to deposit a continuous PVD W film at the high sloped area of the capping layer. Once the pull-back process has been completed, a selective metal deposition process, for example, a tungsten or molybdenum deposition process, can either partially or fully fill up the via. For example, a feature is filled with a low resistivity metal, either by cobalt (Co), molybdenum (Mo), or tungsten (W). Such an integration flow not only has high resistivity due to the TiSi/TiSiN bilayer, but also high cost due to the expensive thick FFW ALD deposition process and the pull-back process for thick TiN/PVD W.

In one or more embodiments, a plasma pull-back etch process is used to remove TiSi residue formed along the sidewall surfaces and field regions of the feature, which opens the process window to achieve selective bottom-up metal capping for advanced node structures. The bottom-up metal capping replaces current TiSiN or TiSiN/TiN capping on TiSi. Existing flows focus on ex-situ and rely on TiSiN or TiSiN/TiN capping, which has a much thicker TiSiN/TiN deposition, for example, 20 to 30 Å along the sidewall and field before vacuum break. The thickness of the TiSiN/TiN deposition increases the amount of etching needed during the pull-back process.

In one or more embodiments, a pre-clean process, for example, NF3/NH3 plasma or thermal HF/NH3, is performed to remove native oxides formed on silicon surfaces. A plasma-enhanced titanium deposition process is performed to grow TiSi on silicon and deposit TiSi residue on exposed dielectric surfaces. The plasma-enhanced titanium deposition process includes exposing the silicon surfaces and dielectric surfaces to a TiCl4/H2/Ar plasma. The selective pull-back process includes using a CH4/Ar plasma to form a carbon passivation layer over the TiSi layer. The selective pull-back process further includes exposing the carbon passivation layer to a trim process to remove the carbon passivation layer formed over the TiSi layer on the field region and the sidewalls while the carbon passivation layer or carbon cap remains over the bottom surface. The trim process includes exposing the carbon passivation layer to hydrogen plasma. The selective pull-back process further includes removing the exposed portions of the TiSi layer to an etching process to remove the exposed portions of the TiSi layer. The etching process includes a CH4/Cl2 plasma. The selective pull-back process further includes exposing the carbon cap layer to a hydrogen plasma to remove the carbon cap layer. A metal capping layer, for example, a molybdenum capping layer is selectively grown from the TiSi layer by a bottom-up growth process which selectively grows on the bottom TiSi layer relative to the dielectric sidewall surfaces. The bottom-up growth process can include a thermal MoCl5/H2 process to selectively grow the molybdenum on the bottom TiSi.

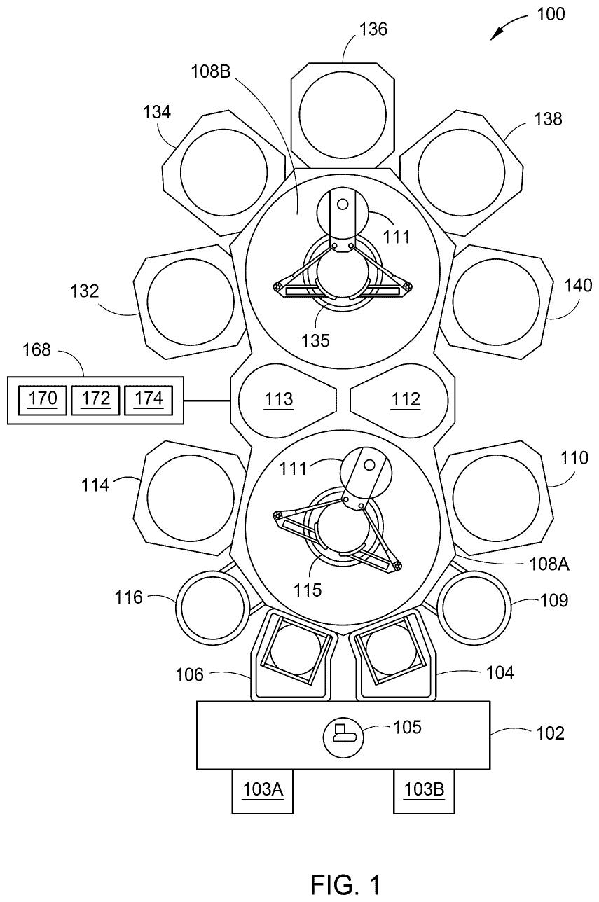

FIG. 1 is a schematic top view of a multi-chamber processing system 100 (also referred to as a “processing platform” or a “processing system”) in accordance with one or more embodiments described herein. The multi-chamber processing system 100 can be used for forming low resistivity contacts without breaking vacuum in accordance with one or more implementations of the present disclosure. The processing system 100 generally includes a factory interface 102 for loading substrates into the processing system 100, a first load lock chamber 104 and a second load lock chamber 106 coupled to the factory interface 102, transfer chambers 108A, 108B with respective transfer robots 115, 135, pass-through chambers 112, 113, and processing chambers 110, 114, 132, 134, 136, 138, and 140. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

The factory interface 102 generally includes one or more robots 105 that are configured to transfer substrates from front opening unified pods (FOUPs) 103A, 103B to at least one of the first load lock chamber 104 or the second load lock chamber 106. In some examples, each factory interface robot 105 generally includes a blade disposed on one end of the respective factory interface robot 105 adapted to transfer the substrates from the factory interface 102 to the load lock chambers 104, 106.

The load lock chambers 104, 106 have respective ports coupled to the factory interface 102 and respective ports coupled to the transfer chamber 108A. The transfer chamber 108A further has respective ports coupled to the pass-through chambers 112, 113 and respective ports coupled to the processing chambers 110, 114. Similarly, the transfer chamber 108B has respective ports coupled to the pass-through chambers 112, 113 and respective ports coupled to the processing chambers 110, 114, 132, 134, 136, 138, and 140. The ports can be, for example, slit valve openings with slit valves for passing substrates therethrough by the transfer robots 115, 135 and for providing a seal between respective chambers to prevent a gas from passing between the respective chambers. Generally, any port is open for transferring a substrate therethrough. Otherwise, the port is closed.

The load lock chambers 104, 106, the transfer chambers 108A, 108B, the pass-through chambers 112, 113 and the processing chambers 110, 114, 132, 134, 136, 138, and 140 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, the factory interface robot 105 transfers a substrate from a FOUP 103A, 103B through to a load lock chamber 104 or 106. The gas and pressure control system then pumps down the load lock chamber 104 or 106. The gas and pressure control system further maintains the transfer chambers 108A, 108B and the pass-through chambers 112, 113 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the first transfer chamber 108A.

Proceeding counterclockwise around the first transfer chamber 108A from the first load lock chamber 104, the processing system 100 includes a first degas chamber 109, a first pre-clean chamber 110, the first pass-through chamber 112, the second pass-through chamber 113, a second pre-clean chamber 114, a second degas chamber 116 and the second load lock chamber 106. The first transfer chamber 108A includes the first transfer robot 115 that is configured to transfer a substrate 111 to each of the load lock chambers 104, 106, the degas chambers 109, 116, the pre-clean chambers 110, 114 and the pass-through chambers 112, 113. With the substrate in the load lock chamber 104 or 106 that has been pumped down, the transfer robot 115 transfers the substrate 111 from the load lock chamber 104 or 106 into the transfer chamber 108A. The transfer robot 115 is then capable of transferring the substrate 111 to and/or between any of the processing chambers 110, 114 through the respective ports for processing and the pass-through chambers 112, 113 through the respective ports for holding to await further transfer.

Similarly, the second transfer robot 135 in the second transfer chamber 108B is capable of accessing the substrate 111 in the pass-through chambers 112, 113 through the port and is capable of transferring the substrate to and/or between any of the processing chambers 132, 134, 136, 138, and 140 through the respective ports for processing and the pass-through chambers 112, 113 through the respective ports for holding to await further transfer. The transfer and holding of the substrate within and among the various chambers can be in the low pressure or vacuum environment provided by the gas and pressure control system.

The processing chambers 132, 134, 136, 138, 140 can be any appropriate chamber for processing a substrate. The processing chambers can include a first processing chamber 132, a second processing chamber 134, a third processing chamber 136, a fourth processing chamber 138, and a fifth process chamber 140. In general, the processing chambers 132, 134, 136, 138, 140 can include an atomic layer deposition (ALD) chamber, microwave chamber, chemical vapor deposition (CVD) chamber, physical vapor deposition (PVD) chamber, etch chamber, degas chamber, an anneal chamber, or other type of semiconductor substrate processing chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective PVD, CVD or ALD deposition processes. The processing chamber 110 may be a Selectra™ Etch chamber available from Applied Materials of Santa Clara, Calif. The processing chamber 114 may be a SiCoNi™ Pre-clean chamber available from Applied Materials of Santa Clara, Calif. The processing chamber 132, 134, 136, 138, or 140 may be a TERSA® chamber and/or a TRILLIUM® ALD chamber available from Applied Materials of Santa Clara, Calif.

A system controller 168, such as a programmable computer, is coupled to the processing system 100 for controlling the processing system 100 or components thereof. For example, the system controller 168 may control the operation of the processing system 100 using a direct control of the chambers 104, 106, 109, 110, 114, 116, 132, 134, 136, 138, 140 of the processing system 100 or by controlling controllers associated with the chambers 104, 106, 109, 110, 114, 116, 132, 134, 136, 138, 140. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Processes, for example, one or more of operations 210-270, may generally be stored in the memory of the system controller 168 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, for example, an application specific integrated circuit or other type of hardware embodiment, or as a combination of software and hardware. The software routine, when executed by the processor, transforms the general-purpose computer into a specific purpose computer (controller) that controls the chamber operation such that the processes are performed.

Other processing systems can be in other configurations. For example, more or fewer processing chambers may be coupled to a transfer apparatus. In the illustrated example, the transfer apparatus includes the transfer chambers 108A, 108B and the pass-through chambers 112, 113. In other examples, more or fewer transfer chambers (e.g., one transfer chamber) and/or more or fewer holding chambers (e.g., no holding chambers) may be implemented as a transfer apparatus in a processing system.

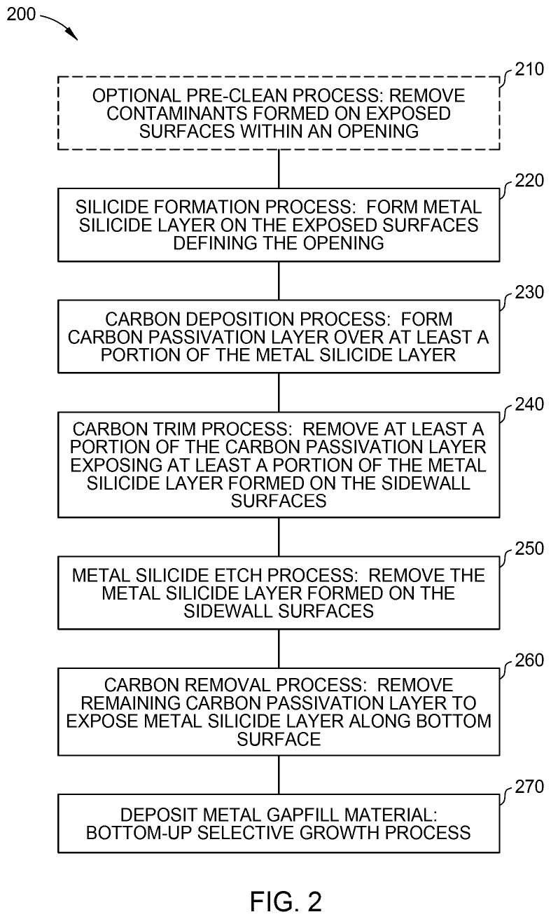

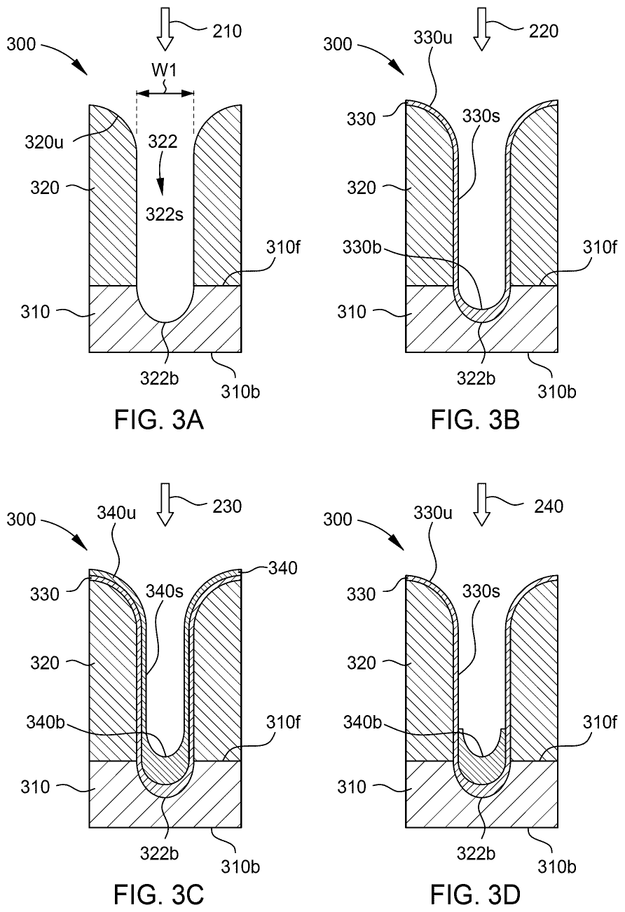

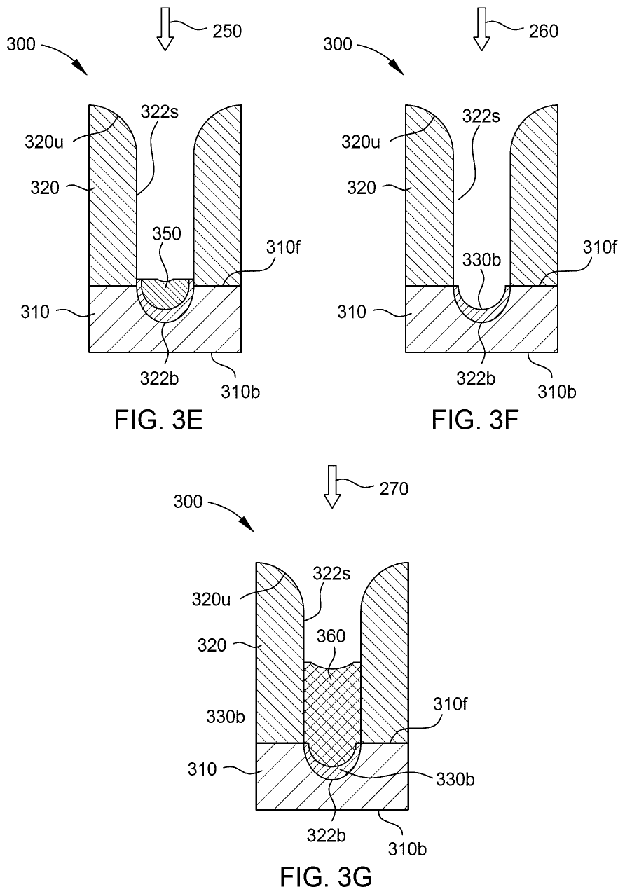

FIG. 2 illustrates a process flow diagram of a method 200 of forming a metal silicide layer in a semiconductor structure in accordance with one or more embodiments of the present disclosure. FIGS. 3A-3G illustrate cross-sectional views of a portion of a semiconductor structure corresponding to various states of the method 200 of FIG. 2 in accordance with one or more embodiments of the present disclosure. With reference to FIGS. 3A-3G, schematic views of a semiconductor device structure 300 at various stages of manufacture are provided to illustrate the method of FIG. 2. Although FIGS. 3A-3G are described in relation to the method 200, it will be appreciated that the structures disclosed in FIGS. 3A-3G are not limited to the method 200, but instead may stand alone as structures independent of the method 200. Similarly, although the method 200 is described in relation to FIGS. 3A-3G, it will be appreciated that the method 200 is not limited to the structures disclosed in FIGS. 3A-3G, but instead may stand alone independent of the structures disclosed in FIGS. 3A-3G. It should also be noted that although the method illustrated in FIG. 2 is described sequentially, other process sequences that include one or more operations that have been omitted and/or added, and/or have been rearranged in another desirable order, fall within the scope of the embodiments of the disclosure provided herein.

Referring to FIG. 3A, a semiconductor device structure 300 having at least one feature 322 is received. The semiconductor device structure 300 includes a device substrate 310 having one or more layers formed thereon, for example, a dielectric layer 320 as is shown in FIG. 3A. The device substrate 310 has a frontside 310f (also referred to as a front surface) and a backside 310b (also referred to as a back surface) opposite the frontside 310f. The dielectric layer 320 is formed over the frontside 310f of the device substrate 310. The dielectric layer 320 may include multiple layers. The dielectric layer 320 includes an upper surface 320u or field region. In some embodiments, the dielectric layer 320 includes silicon oxide, silicon oxynitride, silicon nitride, a combination thereof, or multi-layers thereof. In some embodiments, the dielectric layer 320 consists essentially of silicon nitride. It is noted that the foregoing descriptors (e.g., silicon nitride) should not be interpreted to disclose any particular stoichiometric ratio. Accordingly, “silicon nitride” and the like will be understood by one skilled in the art as a material consisting essentially of silicon and nitrogen without disclosing any specific stoichiometric ratio.

The device substrate 310 may be or include a bulk semiconductor substrate, a semiconductor-on-insulator (SOI) substrate, or the like, which may be doped, for example, with a p-type dopant or an n-type dopant, or undoped. In some embodiments, the semiconductor material of the device substrate 310 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 310 may include additional materials, for example, silicide layers, metal silicide layers, metal layers, dielectric layers, etch stop layers, interlayer dielectrics, or a combination thereof. The device substrate 310 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 310 to generate the structural and functional requirements of the design for the resulting semiconductor device structure 300.

The dielectric layer 320 is patterned to form one or more feature(s) 322. The feature 322 can also be referred to as a cavity, via, trench, or opening. The feature 322 may be a high aspect ratio (HAR) feature. In some embodiments, the feature 322 can be selected from a trench, a via, a hole, or combinations thereof. In particular embodiments the feature 322 is a via. In some embodiments, the feature 322 extends from the upper surface 320u of the dielectric layer 320 to the frontside 310f of the device substrate 310. The feature 322 includes sidewall surface(s) 322s and a bottom surface 322b extending between the sidewall surface(s) 322s, which define an opening. In some embodiments, the sidewall surface(s) 322s is tapered. The sidewall surface(s) 322s may be defined by the dielectric layer 320 and the bottom surface may be defined by the device substrate 310, for example, a silicon material. In some embodiments, the sidewall surface(s) 322s may be defined by the dielectric layer 320 and the bottom surface may also be defined by the dielectric layer 320. The feature 322 has a first depth “D1” from the upper surface 320u to the bottom surface 322b and a width “W1” between the two sidewall surface(s) 322s.

In one or more embodiments, the feature 322 or cavity can have an average width. For example, the feature 322 can have a width “W1” (shown in FIG. 3A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, the feature 322 can have an average critical dimension of about 1 nanometer (nm) to about 20 nm. For example, the feature 322 can have a critical dimension, for example, a width between opposing sidewall surface(s) of the feature 322, of about 20 nanometers (nm) or less, such as about 1 nm to about 15 nm, such as about 1 nm, 5 nm, and 10 nm to about 12 nm, 15 nm, or 20 nm. Without being bound by theory, the present methods can allow for the deposition of a molybdenum gapfill material having no and/or reduced seams within the gapfill material. In one or more embodiments, the feature 322 can have an aspect ratio (depth: width) of about 1:1 to about 100:1, such as about 10:1, 15:1, or 25:1 to about 35:1, 45:1, or 50:1.

Referring to FIG. 3A, optionally at operation 210, a pre-clean process is performed to remove contaminants, such as native oxides, from the exposed surfaces within the feature 322, for example, the sidewall surface(s) 322s, the bottom surface 322b, and the upper surface 322u. In one or more embodiments, the pre-clean process to remove oxide-containing contaminants may include an isotropic etch process, such as a wet etch process using distilled hydrofluoric acid (d-HF) solution, or a dry chemical etch process using ammonia (NH₃) and nitrogen trifluoride (NF3), for example a thermal etch using NH3 and NF3 or a plasma etch using a plasma formed from NH3, NF3, and HF. The etch process is selective for oxide layers, and thus does not readily etch silicon, germanium, or nitride layers regardless of whether the layers are amorphous, crystalline or polycrystalline. Selectivity of the etch process for oxide versus silicon or germanium is at least about 3:1, and usually 5:1 or better, sometimes 10:1. In one or more other embodiments, the pre-clean process to remove oxide-containing contaminants may include an anisotropic remote plasma assisted dry etch process, such as a reactive ion etching (RIE) process, using a plasma formed from a gas including hydrogen (H), argon (Ar), helium (He), or a combination thereof.

Referring to FIG. 3B, at operation 220, a silicide formation process is performed. The silicide formation process includes forming a metal silicide layer 330 on the exposed surfaces defining the feature 322, for example, the sidewall surface(s) 322s, the bottom surface 322b, and the upper surface 322u. The metal silicide layer 330 includes a bottom portion 330b formed on the bottom surface 322b, a sidewall portion 330s formed on the sidewall surface(s) 322s, and an upper portion 330u formed on the upper surface 322u. During operation 220, as shown in FIG. 3B, a deposition process is performed to produce the metal silicide layer 330, such as a titanium containing layer, a molybdenum containing layer, and/or a tungsten containing layer, on the sidewall surface(s) 322s, the bottom surface 322b, and the upper surface 322u of the feature 322. For example, the metal silicide layer 330 can include a Ti layer and/or a TiSi layer. TiSi is TiₓSi_{y} which may include Ti₅Si₃, TiSi₂, TiSi, or combinations thereof. The process includes forming the titanium silicide containing layer over the bottom surface 322b and over the dielectric layer 320 formed on the device substrate 310. In some embodiments, the deposition process is a CVD process, for example, a plasma enhanced CVD process (PECVD). The deposition process of operation 220 can provide a thickness of metal layer of approximately 1 nm to approximately 5 nm on the sidewall surface(s) 322s, the bottom surface 322b, and/or the upper surface 322u. In some embodiments, the thickness of the metal silicide layer 330 is conformal along the sidewall surface(s) 322s and/or the bottom surface 322b. In some embodiments, the thickness of the sidewall portion 330s of the metal silicide layer 330 formed on the sidewall surface(s) is less than a thickness of the bottom portion 330b of the metal silicide layer 330 formed on the bottom surface 322b.

The TiSi deposition during operation 220 can be performed using any suitable thermal or plasma enhanced CVD or ALD process. In some embodiments, the CVD or ALD process includes utilizing a plasma that includes precursors. A carrier gas may be utilized in the CVD or ALD process. The plasma/carrier gas may then be introduced towards the surface of the semiconductor substrate. In one or more embodiments, the carrier gas includes a noble gas, such as argon, neon, helium, or combinations thereof.

In one or more embodiments, deposition during operation 220 is performed by introducing a hydrogen-containing precursor and a metal-containing precursor followed by a capacitively coupled plasma (CCP) deposition process. In one or more embodiments, deposition includes introducing a hydrogen-containing precursor and a metal-containing precursor with the carrier gas for thermal reaction. In one or more embodiments, the metal-containing precursor gas may be fluorine free to prevent formation of metal fluoride solids that have undesirable resistivity properties. For example, the hydrogen-containing precursor can include molecular hydrogen (H₂) and the metal-containing precursor is titanium chloride (TiCl₄). Without being bound by theory, the introduction of both the hydrogen-containing and the metal-containing precursors via carrier gas causes both precursors to become energized on a molecular level to a point of at least partial disassociation in the carrier gas. For example, titanium chloride may disassociate into titanium-based ions (Ti⁺, TiClₓ⁺) or free radial titanium trichloride (TiCl₃*); hydrogen may disassociate into hydronium ions (H⁺) or hydrogen free radicals (H*). The dissociated species may then interact with the silicon surface of the sidewall surface(s) 322s, the bottom surface 322b, and/or the upper surface 322u, donate electrons to the silicon atoms and then each species interact with one another to form the titanium silicide layer on the sidewall surface(s) 322s, the bottom surface 322b, and/or the upper surface 322u. In one or more embodiments, a TiCl4/H2/Ar plasma is used to form the metal silicide layer 330.

In one or more embodiments, the deposition of operation 220 is performed by maintaining the semiconductor substrate at a metal deposition temperature. In one or more embodiments, the semiconductor substrate is maintained at a metal deposition temperature of about 200 °C to 800 °C, such as about 200 °C, 300 °C, 400 °C, 450 °C, and 500 °C to about 600 °C, 700 °C, and 800 °C, for a period of about 5 seconds to about 100 seconds, in which an inert gas may be present. The inert gas flowing over the semiconductor substrate may facilitate in cooling and affixing the deposition material (e.g., TiSi) on the top of the silicon-containing contact as well as removing volatilized byproducts and unreacted materials, such as molecular hydrogen, hydrogen chloride (HCl), and/or TiClₓ.

Referring to FIG. 3C, at operation 230, a carbon deposition process is performed. The carbon deposition process includes forming a carbon-containing passivation layer 340 over at least a portion of the metal silicide layer 330, for example, the bottom portion 330b of the metal silicide layer 330, the sidewall portion 330s of the metal silicide layer 330, and the upper portion 330u of the metal silicide layer 330. The deposition of operation 230 may be performed in inductively coupled plasma containing carbon-based precursors and a dilution gas such as Ar, for example, methane and argon. The deposition process of operation 230 can be performed at a temperature in a range from about 0 °C to about 50 °C, a pressure in a range from about 5 mT to about 100 mT, and a flow regime in a range from about 50 sccm to about 500 sccm. The one or more carbon-containing precursors can be used to provide the carbon at the surface of the metal silicide layer 330. The one or more carbon-containing precursors can include carbon precursors such as methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), isomers thereof, or a combination thereof. The deposition process of operation 230 results in the carbon-containing passivation layer 340 disposed over at least a portion of the metal silicide layer 330. The carbon-containing passivation layer 340 includes a bottom portion 340b formed on the bottom portion 330b of the metal silicide layer 330, a sidewall portion 340s formed on the sidewall portion 330s of the metal silicide layer 330, and an upper portion 340u formed on the upper portion 330u of the metal silicide layer 330. The deposition process of operation 230 can be performed using any suitable CVD or ALD process with plasma capability. In one or more embodiments, the carrier gas includes a noble gas, such as argon, neon, helium, or combinations thereof. In one or more embodiments, the bottom portion 340b has a thickness that is greater than a thickness of the sidewall portion 340s and/or the upper portion 340u. The carbon-containing passivation layer 340 can have a thickness in a range from about 3 nm to about 9 nm along the sidewall surface(s) 322s and the upper surface 322u and a thickness in a range from about 2 nm to about 10 nm along the upper surface 322u. In some embodiments, the thickness of the carbon-containing passivation layer 340 is conformal along the sidewall surface(s) 322s and the bottom surface 322b.

Referring to FIG. 3D, at operation 240, a carbon trim process is performed. The carbon trim process includes removing at least a portion of the carbon-containing passivation layer 340, for example, the sidewall portion 340s and/or the upper portion 340u of the carbon-containing passivation layer 340, exposing at least a sidewall portion of the metal silicide layer 330, for example, the sidewall portion 330s and/or the upper portion 330u of the metal silicide layer 330. The carbon trim process of operation 240 includes exposing the carbon-containing passivation layer 340 to a first hydrogen plasma, for example, a non-ionizing H₂ plasma. The plasma generated may have the etchants dissociated to form relatively mild and gentle etchants, so as to gradually etch the carbon-containing passivation layer 340 from the metal silicide layer 330. The H₂ plasma etches or “trims” the carbon-containing passivation layer 340. In one or more embodiments, at least a portion of the carbon-containing passivation layer 340 is etched away from the metal silicide layer 330 such that at least a portion of the carbon-containing passivation layer 340 remains on the metal silicide layer 330. For example, the H₂ plasma removes at least the sidewall portion 340s and/or the upper portion 340u of the carbon-containing passivation layer 340 from the metal silicide layer 330, exposing the sidewall portion 330s and/or the upper portion 330u of the metal silicide layer 330 while the bottom portion 340b of the carbon-containing passivation layer 340 remains forming a carbon-containing passivation cap 350 on the bottom portion 330b of the metal silicide layer 330 as shown in FIG. 3D.

In one or more embodiments, the H₂ plasma is formed by supplying a hydrogen containing gas and an inert gas to a processing chamber. Suitable examples of the hydrogen containing gas include H₂, H₂°, H₂O₂, and the like. The inert gas may also be supplied into the gas mixture as needed. Suitable examples of the inert gas include Ar, He, Ne, Kr, Xe, and the like. In at least one embodiment, the gas mixture includes H₂. In at least one embodiment, the etching gas mixture includes H₂ without an inert gas, for example, the etching gas mixture is free or substantially free from an inert gas.

In at least one embodiment, H₂ is flowed into a processing chamber at a flow rate in a range from about 200 sccm to about 2,000 sccm. A carrier gas may optionally be supplied into the processing chamber at a ratio of H₂ to carrier gas of about 5:95 to about 99.8:0.2. In at least one embodiment, He is used as the carrier gas and the He is supplied into the processing chamber at a H₂: He ratio of 5:95. The processing chamber can be operated at a temperature of about 0 °C to about 50 °C, a pressure of about 5 mT to about 500 mT, and a radio-frequency (RF) power of about 200 W to about 1,000 W for about 60 seconds to about 300 seconds.

Referring to FIG. 3E, at operation 250, a metal silicide etch process is performed. The metal silicide etch removes at least a portion of the metal silicide layer 330, for example, the sidewall portion 330s and/or the upper portion 330u of the metal silicide layer 330, exposing at least a portion of the sidewall surface, for example, the sidewall surface(s) 322s and/or the upper surface 322u of the feature 322 while the carbon-containing passivation cap 350 protects the bottom portion 330b of the metal silicide layer 330. The metal silicide etch process includes immersing the feature in an inductively coupled plasma containing Cl₂ and other dilution gases, typically operated at about 5 mT to about 100 mT with a total gas flow of about 60 sccm to about 500 sccm and a plasma power of about 100 W to about 500 W. The inductively coupled plasma may further include one or more carbon-containing precursors as described. In one or more embodiments, the plasma is formed from Ar/Cl2/CH4. In one or more embodiments, the substrate is maintained at a temperature of between 0 °C and 50 °C. In one or more embodiments, the feature is immersed in the above mentioned Cl₂ plasma for about 10 seconds to about 60 seconds, such as for about 50 seconds. The metal silicide etch process may continue for any amount of time until the metal silicide layer 330 is etched away to a targeted height. In one or more embodiments, the metal silicide etch process is repeated in a cycle for R times. The cycle is repeated until the metal silicide layer 330 is etched away to a targeted height. For example, as shown in FIG. 3E the exposed portions of the metal silicide layer 330 are etched away from a portion of the sidewall surface(s) 322s and/or the upper surface 322u while the bottom portion 330b of the metal silicide layer 330, which is protected by the carbon-containing passivation cap 350, remains on the bottom surface 322b of the feature 322.

Referring to FIG. 3F, at operation 260, a carbon removal process is performed. The carbon removal process of operation 260 includes removing the remaining carbon passivation layer, for example the carbon-containing passivation cap 350, to expose the metal silicide layer along the bottom surface 322b, for example, the bottom portion 330b of the metal silicide layer 330. The carbon removal etch treatment includes exposing the carbon-containing passivation layer 340 disposed over the metal silicide layer 330 to a second hydrogen plasma, for example, a non-ionizing H₂ plasma, such that the carbon-containing passivation layer 340 is etched away. As shown in FIG. 3F, the carbon-containing passivation cap 350 is etched away and the bottom portion 330b of the metal silicide layer 330 remains on the bottom surface 322b of the feature 322. The H₂ plasma is formed by supplying a hydrogen containing gas and optionally an inert gas to a processing chamber. Suitable examples of the hydrogen containing gas include H₂, H₂O, H₂O₂, and the like. An inert gas may also be supplied into the gas mixture as needed. Suitable examples of the inert gas include Ar, He, Ne, Kr, Xe and the like. In at least one embodiment, the etching gas mixture includes H₂ without an inert gas, for example, the etching gas mixture is free or substantially free from an inert gas.

In at least one embodiment, which can be combined with other embodiments, the carbon removal process includes, flowing H₂ into a processing chamber at a flow rate of about 200 sccm to about 5,400 sccm. A carrier gas may optionally be supplied into the processing chamber at a ratio of H₂ to carrier gas of about 5:95 to about 99.8:0.2. In at least one embodiment, He is used as the carrying gas and the He is supplied into the processing chamber at a H₂: He ratio of 5:95. In at least one embodiment, water (H₂°) is used in place of the carrier gas and the H₂O is supplied into the processing chamber at a H₂:H₂O ratio of 99.6:0.4. The processing chamber is operated at a temperature of about 120 °C to about 350 °C, a process pressure of about 50 mT to about 20 T, and a radio-frequency (RF) power of about 200 W to about 3600 W for about 60 seconds to about 300 seconds.

In one or more embodiments, the carbon deposition process of operation 230, the carbon trim process of operation 240, the metal silicide etch process of operation 250, and the carbon removal process of operation 260 as a part of a selective etching process. The selective etching process can be performed in-situ in a processing region of a single processing chamber. In some embodiments where the selective etching process is performed in-situ, a purge process is performed to remove any remaining plasma gases and any byproducts from the processing region. For example, plasma gases and reaction byproducts (if any) may be removed from the surface of the semiconductor device structure 300, for example, by pumping with inert gas. In some embodiments, where an inert carrier gas is introduced into the processing region with the precursor gases, the flow of the precursor gases may be stopped while the inert carrier gas continues to flow to purge the processing region. In some embodiments, excess vapor phase reactants, such as for example, excess precursor gases, plasma effluents, and possible reaction byproducts may be removed with the aid of a vacuum, generated by a pumping system in fluid communication with the processing region.

Referring to FIG. 3G, at operation 270, a metal gapfill material process is performed. The metal gapfill process includes bottom-up selective growth of a metal gapfill material 360 which is also referred to as a metal capping layer, from the bottom portion 330b of the metal silicide layer 330. The metal gapfill material 360 has been deposited into the feature 322, thus partially filling the feature 322. The metal gapfill material 360 is shown in contact with the bottom portion 330b of the metal silicide layer 330. The metal gapfill material 360 is also in contact with at least a portion of the sidewall surface(s) 322s. The metal gapfill process can be done by selective Mo fill or conformal Mo fill. In some embodiments, Mo and W materials can be interchanged or a mixture of Mo and W can be used.

Any suitable chemical deposition process, including but not limited to CVD or ALD processes, may be utilized for the metal gapfill material process of operation 270. The metal gapfill material 360 may be applied such that the material is deposited onto the bottom portion of the device feature and then grown upwards towards the semiconductor field region, for example, the upper surface 322u of the feature 322, that the resultant gapfill material at least approaches the field region (as shown in FIG. 3G) or is at least partially level with the field region (not shown).

In one or more embodiments, the metal gapfill material 360 includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or any combination thereof. In one or more embodiments, the metal gapfill material includes molybdenum.

In at least one embodiment, which can be combined with other embodiments, during the deposition process of operation 270, a precursor containing the gapfill metal (e.g., molybdenum (Mo)), such as molybdenum (Mo)-containing halide precursor (e.g., molybdenum pentachloride (MoCl₅), molybdenum oxytetrachloride (MoOCl₄)), and hydrogen (H₂) precursor are flowed in the processing chamber. The deposition process may be performed at a first deposition temperature in a range from about 320 °C and about 450 °C at a pressure in a range from about Torr to about 300 Torr. During the deposition process, hydrogen (H₂) gas may be supplied at a flow rate of between about 0 sccm and about 15,000 sccm.

After a cycle of the deposition process, one or more cycles can be repeated with an optional purge between cycles, until a targeted thickness of the metal gapfill material 360 is achieved. During the purge, a purge gas, which can be argon (Ar), is introduced in the processing chamber. In some embodiments, the purge gas includes hydrogen (H₂) gas.

The previously described embodiments of the present disclosure have many advantages. In one or more embodiments of the present disclosure, deposition of a multi-layer epitaxial source/drain material is performed. The currently available TiSiN/TiN cap is replaced with a metal cap, which reduces contact resistance. The integrated pull-back process presents less of an etching challenge for removing TiSi residue relative to currently available processes. The pull-back process described herein increases pullback efficiency. However, the present disclosure does not necessitate that all the advantageous features and all the advantages need to be incorporated into every embodiment of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, embodiment, embodiment, or example of the present disclosure, or a particular claim, that feature can also be used, to the extent possible in combination with and/or in the context of other particular aspects and embodiments of the present disclosure, and in the present disclosure generally.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A method of forming a contact structure on a semiconductor substrate, comprising:
depositing a carbon-containing passivation layer over a metal silicide layer, the metal silicide layer formed over a bottom surface and sidewall surfaces that define an opening of a feature;
trimming the carbon-containing passivation layer by exposing the carbon-containing passivation layer to a first hydrogen plasma so that a first portion of the carbon-containing passivation layer is etched away exposing at least a first portion of the metal silicide layer formed over the sidewall surfaces while a second portion of the carbon-containing passivation layer remains over a second portion of the metal silicide layer formed over the bottom surface;
exposing the first portion of the metal silicide layer to an etchant gas to remove the first portion of the metal silicide layer formed over the sidewall surfaces; and
exposing the second portion of the carbon-containing passivation layer remaining over the bottom surface to a second hydrogen plasma so that the second portion of the carbon-containing passivation layer is removed exposing the second portion of the metal silicide layer formed over the bottom surface.

2. The method of claim 1, wherein the metal silicide layer comprises titanium silicide.

3. The method of claim 1, further comprising depositing a metal gapfill material over the second portion of the metal silicide layer formed over the bottom surface.

4. The method of claim 3, wherein the metal gapfill material comprises titanium, tungsten, molybdenum, or combinations thereof.

5. The method of claim 4, wherein depositing the metal gapfill material comprises a bottom-up growth process.

6. The method of claim 1, wherein depositing the carbon-containing passivation layer comprises forming an inductively coupled plasma comprising argon and methane.

7. The method of claim 1, wherein exposing the carbon-containing passivation layer to the first hydrogen plasma comprises flowing hydrogen gas at a first flow rate and at a first power.

8. The method of claim 7, wherein exposing the second portion of the carbon-containing passivation layer remaining over the bottom surface to the second hydrogen plasma comprises flowing hydrogen gas at a second flow rate and at a second power, the second flow rate greater than the first flow rate and the second power less than the first power.

9. The method of claim 1, wherein the etchant gas comprises chlorine and methane.

10. A method of forming a contact structure on a semiconductor substrate, comprising:
forming a metal silicide layer over a surface of the contact structure, wherein:
the contact structure comprises a feature formed in a surface of the semiconductor substrate;
the feature comprises a bottom surface and sidewall surfaces that define an opening, which comprise a dielectric material; and
the metal silicide layer is formed over the sidewall surfaces and the bottom surface;
performing a selective etch process, the selective etch process comprising:
a deposition operation, wherein the deposition operation comprises forming a carbon-containing passivation layer over the metal silicide layer;
a trim operation, wherein the trim operation comprises exposing the carbon-containing passivation layer to a first hydrogen plasma so that a first portion of the carbon-containing passivation layer is etched away exposing at least a first portion of the metal silicide layer formed over the sidewall surfaces while a second portion of the carbon-containing passivation layer remains over a second portion of the metal silicide layer formed over the bottom surface;
an etch operation, wherein the etch operation comprises exposing the first portion of the metal silicide layer formed over the sidewall surfaces to an etchant gas to remove the first portion of the metal silicide layer formed over the sidewall surfaces; and
a carbon removal operation, wherein the carbon removal operation comprises exposing the second portion of the carbon-containing passivation layer to a second hydrogen plasma so that the second portion of the carbon-containing passivation layer is removed exposing the second portion of the metal silicide layer formed over the bottom surface; and
depositing a metal gapfill material over the second portion of the metal silicide layer formed over the bottom surface.

11. The method of claim 10, wherein the metal silicide layer comprises titanium silicide.

12. The method of claim 10, wherein the metal gapfill material comprises titanium, tungsten, molybdenum, or combinations thereof.

13. The method of claim 10, wherein forming the carbon-containing passivation layer over the metal silicide layer comprises:
delivering a carbon-containing precursor that comprises methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), isomers thereof, or a combination thereof to the feature;
delivering the carbon-containing precursor to the feature at a pressure of about 5 mT to about 100 mT; and
heating the semiconductor substrate to a temperature of about 300 °C to 550 °C.

14. The method of claim 10, wherein exposing the carbon-containing passivation layer to the first hydrogen plasma comprises:
delivering a hydrogen containing precursor that comprises H₂, H₂°, H₂O₂, or a combination thereof to the feature;
delivering the hydrogen containing precursor to the feature at a pressure of about 50 mT to about 20 T; and
heating the semiconductor substrate to a temperature of about 120 °C to 350 °C.

15. The method of claim 10, wherein exposing the first portion of the metal silicide layer to the etchant gas comprises:
delivering an inductively coupled plasma comprising Cl₂ to the feature at a flow rate of about 60 sccm to about 500 sccm, a pressure of about 5 mT to about 100 mT, and a temperature of about 0 °C to about 50 °C.

16. The method of claim 10, where exposing the second portion of the carbon-containing passivation layer to the second hydrogen plasma comprises:
delivering a hydrogen containing precursor that comprises H₂, H₂°, H₂O₂, or a combination thereof to the feature;
delivering the hydrogen containing precursor to the feature at a pressure of about 50 mT to about 20 T; and
heating the semiconductor substrate to a temperature of about 120 °C to 350 °C.

17. The method of claim 10, wherein depositing the metal gapfill material comprises depositing the metal gapfill material using a chemical vapor deposition process.

18. A processing system, comprising:
a first processing chamber; and
a system controller, comprising:
a memory for storing computer readable instructions; and
a processor coupled to the memory, the processor configured by the computer readable instructions that when executed by the processor perform a plurality of operations, comprising:
depositing a carbon-containing passivation layer over a metal silicide layer, the metal silicide layer formed over a bottom surface and sidewall surfaces that define an opening of a feature formed on a semiconductor substrate;
trimming the carbon-containing passivation layer by exposing the carbon-containing passivation layer to a first hydrogen plasma so that a first portion of the carbon-containing passivation layer is etched away exposing at least a first portion of the metal silicide layer formed over the sidewall surfaces while a second portion of the carbon-containing passivation layer remains over the bottom surface;
exposing the first portion of the metal silicide layer to an etchant gas to remove the first portion of the metal silicide layer formed over the sidewall surfaces; and
exposing the second portion of the carbon-containing passivation layer remaining over the bottom surface to a second hydrogen plasma so that the second portion of the carbon-containing passivation layer is removed exposing the second portion of the metal silicide layer formed over the bottom surface.

19. The processing system of claim 18, wherein depositing the carbon-containing passivation layer, trimming the carbon-containing passivation layer, exposing the first portion of the metal silicide layer to the etchant gas, and exposing the second portion of the carbon-containing passivation layer remaining over the bottom surface to the second hydrogen plasma are performed in the first processing chamber.

20. The processing system of claim 18, wherein the metal silicide layer comprises titanium silicide.
